(19) United States
(12) Patent Application Publication
(10) Pub. No.: US 2026/0148788 A1
(43) Pub. Date: May 28, 2026

(54) HARDWARE-BASED TRAINING FOR SYNCHRONOUS DYNAMIC RANDOM-ACCESS MEMORY

(71) Applicant: QUALCOMM Incorporated, San Diego, CA (US)

(72) Inventors: Farrukh AQUIL, San Diego, CA (US); Boris Dimitrov ANDREEV, San Diego, CA (US)

(21) Appl. No.: 18/932,043

(22) Filed: Oct. 30, 2024

(51) Int. Cl. G11C 29/12; G11C 29/20

(52) U.S. Cl. CPC G11C 29/1201; G11C 29/12015; G11C 29/20

(57) ABSTRACT

Hardware-based training is described for synchronous dynamic random-access memory. In one aspect a memory includes a memory physical interface (PHY) of the memory coupled to a memory bus and configured to receive a received Pseudo-Random Binary Sequence (PRBS) through the memory bus at from a host PHY. A PRBS generator is configured to generate a generated PRBS and compare logic is configured to generate a score based on comparing the received PRBS to the generated PRBS. The memory PHY is further configured to send the score to the host PHY.

### TECHNICAL FIELD

The present disclosure relates generally to memory devices and, more particularly, to systems and methods for hardware-based training of a synchronous dynamic random-access memory.

### BACKGROUND

A computing system device (e.g., server, computer, router, mobile phone, etc.) may include one or more processors to perform various functions, such as telephony, wireless data access, camera/video functions, etc. The processor is coupled to a high-speed volatile memory in which processor instructions and data are temporarily stored. One type of memory commonly used in computing devices is known as double data rate (DDR) synchronous dynamic random-access memory (DDR-SDRAM) or DRAM, as used herein. The DRAM may be fabricated on a different die or chiplet from the processor or in a different section of the processor die and is coupled to the processor for control and data communications through a memory bus. In larger systems the DRAM is configured on a separate circuit board and is installed into a socket of a system board through which it connects to the processor. One type of commonly used memory bus for many different configurations is referred to as Low Power Double Data Rate (LPDDR). Specifications for LPDDR are included in the Joint Electron Device Engineering Council (JEDEC) standards.

### BRIEF SUMMARY

The following presents a summary of one or more implementations in order to provide a basic understanding of such implementations. The invention is defined by the independent claims. More particular examples are set out in the dependent claims. Examples and aspects that do not fall within the scope of the claims are merely examples used for explanation of the invention. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

In one aspect, a memory includes a memory physical interface (PHY) of the memory coupled to a memory bus and configured to receive a received Pseudo-Random Binary Sequence (PRBS) through the memory bus at from a host PHY. A PRBS generator is configured to generate a generated PRBS and compare logic is configured to generate a score based on comparing the received PRBS and the generated PRBS. The memory PHY is further configured to send the score to the host PHY.

In another aspect a method includes receiving a received Pseudo-Random Binary Sequence (PRBS) through a memory bus at a memory physical interface (PHY) from a host PHY, generating a generated PRBS at the memory PHY, generating a score based on comparing the received PRBS and the generated PRBS, and sending the score to the host PHY through the memory bus.

In another aspect, a memory apparatus includes means for receiving a received Pseudo-Random Binary Sequence (PRBS) through a memory bus at a memory physical interface (PHY) from a host PHY and means for generating a generated PRBS at the memory PHY. The memory apparatus further includes means for generating a score based on comparing the received PRBS and the generated PRBS and means for sending the score to the host PHY through the memory bus.

To the accomplishment of the foregoing and related ends, the one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the described implementations are intended to include all such aspects and their equivalents.

### BRIEF DESCRIPTION OF THE DRAWINGS

FIG. 1 is a block diagram of an apparatus with a host and a memory coupled through a memory bus according to aspects of the present disclosure.

FIG. 2 is a simplified block diagram of interfaces of a memory bus for training the memory bus according to aspects of the present disclosure.

FIG. 3 is a block diagram of a host PHY of a host coupled to a DRAM PHY of a DRAM through a memory bus configured for training according to aspects of the present disclosure.

FIG. 4 is a process flow diagram of an example training mode operation at a memory PHY according to aspects of the present disclosure.

FIG. 5 is a process flow diagram of an example training mode operation at a host PHY according to aspects of the present disclosure.

FIG. 6 is a process flow diagram of an example write training mode operation according to aspects of the present disclosure.

FIG. 7 is a process flow diagram of an example read training mode operation according to aspects of the present disclosure.

### DETAILED DESCRIPTION

The detailed description set forth below in connection with the appended drawings is intended as a description of various configurations and is not intended to represent the only configurations in which the concepts described herein may be practiced. The detailed description includes specific details for providing a thorough understanding of various concepts. However, it will be apparent to those skilled in the art that these concepts may be practiced without these specific details. In some instances, well known structures and components are shown in block diagram form to avoid obscuring such concepts.

Several aspects of the invention will now be presented with reference to various apparatus and methods. These apparatus and methods will be described in the following detailed description and illustrated in the accompanying drawings by various blocks, modules, components, circuits, steps, processes, algorithms, etc. (collectively referred to as “elements”). These elements may be implemented using electronic hardware, computer software, firmware, or any combination thereof. Whether such elements are implemented as hardware or software depends upon the particular application and design constraints imposed on the overall system.

While aspects and examples are described in this application by illustration to some examples, those skilled in the art will understand that additional implementations and use cases may come about in many different arrangements and scenarios. Innovations described herein may be implemented across many differing platform types, devices, systems, shapes, sizes, and packaging arrangements. For example, aspects and/or uses may come about via integrated chip examples and other non-module-component-based devices (e.g., end-user devices, vehicles, communication devices, computing devices, industrial equipment, retail/purchasing devices, medical devices, artificial intelligence (AI)-enabled devices, etc.).

While some examples may or may not be specifically directed to use cases or applications, a wide assortment of applicability of described innovations may occur. Implementations may range in spectrum from chip-level or modular components to non-modular, non-chip-level implementations and further to aggregate, distributed, or original equipment manufacturer (OEM) devices or systems incorporating one or more aspects of the described innovations. In some practical settings, devices incorporating described aspects and features may also necessarily include additional components and features for the implementation and practice of described examples. It is intended that innovations described herein may be practiced in a wide variety of devices, chip-level components, systems, distributed arrangements, end-user devices, etc., of varying sizes, shapes, and constitution.

According to JEDEC, LPDDR5 SDRAM devices use a command clock (CK) that operates at a reduced rate from a per-byte data clock (WCK). There are seven Double Data Rate (DDR) command/address (CA) pins that the memory controller uses to transmit command, address, bank, configuration, and training information to the DRAM. CA signals are latched on both the rising and falling CK edges when indicated by a high signal on the single data rate (SDR) Chip Select (CS) pin. The Double Data Rate refers to this latching on both the rising and falling edge and applies also to data transfers, e.g., read and write transactions. The memory bus is initialized at a low speed and then training is performed before the memory bus is operated at normal high speed operation modes.

The memory bus uses the write clock (WCK) as a data strobe to send write data across the memory bus and the read data strobe (RDQS) to receive read data across the memory bus on data lines (DQ) of the memory bus. The write training aligns the of the relative phase of the write clock signal with respect to the write data as it is received at the receiver. The relative phase may be calibrated by adjusting the timing of the write clock signal or the write data. In some aspects the relative phase is calibrated by setting a tuning parameter as a delay that is applied to the write data to align the write data phase with the write clock signal. The relative phase of the read data strobe with respect to the read data as it is received at the transmitter is calibrated using read training. Another tuning parameter sets a delay of the read data to align with the phase of the read data strobe.

In some training operations, a data sequence is sent from the processor to the memory at different write clock signal or write data timings to find the write data delay timing that best aligns the data signal path with the write clock signal. A similar operation is performed with read data in which a data sequence is sent from the memory to the processor. The training determines tuning parameters that set an amount of time delay to apply to the write data and the read data to align the phase of the data signals to the respective clock signal. In other aspects, the clock timing is adjusted relative to the data bus, instead of adjusting the data bus timing. The bus voltage may also be trained in a similar way. A voltage (VREF) on the data line for the write data and for the read data may be calibrated using a similar training process and the voltage values determined from the training may be set as tuning parameters in configuration registers with the delay values.

Some commercially available DRAMs provide software-driven training controlled by a processor of the host, e.g., the host processor, to ensure that the write clock (WCK) or data strobe (RDQS) arrives at the receiver latch properly aligned in time with the data (“DQ”) eye. The WCK, RDQS, and DQ are all part of the memory bus that forms the link between the host and the memory. The “eye” refers to the center of the data pulse. A command-based write/read method uses a first-in-first-out (FIFO) buffer in the DRAM to perform write training with predetermined data patterns. The data values written to the FIFO and the data values read from the FIFO may be used to adjust the DQ timing or phase relative to the write clock, also referred to as the WCK-DQ timing. This refers to the WCK, used as a write strobe, and the RDQS, used as the read strobe. A variety of commands from the host processor guide the process to write, read, compare, and determine the results of the training to make suitable timing adjustments. A mis-match between the results of reading the FIFO and the expected data may indicate to the memory controller that the relative timing between the clock and data signals needs to be adjusted.

During the training operations, the memory controller at the host transmits configuration settings to the host physical bus interface (PHY) to adjust configurable delay cells (CDCs) in the host PHY. The write training and read training are repeated for a number of iterations, with the data bus delay being incremented or decremented by a fraction of a clock period on each iteration, until the WCK-DQ timing skew has been swept through an entire period of the data clock, i.e., the entire data eye. After iteratively sweeping the WCK-DQ timing skew through an entire clock period in this manner, based upon the results, i.e., matches and mis-matches between data that was written and data that was read, a determination is made as to the amount of timing delay by which each bit needs to be adjusted, and the corresponding CDCs are then adjusted accordingly. This amount of timing is stored in a configuration register as one of the tuning parameters for use in normal write operations. The DRAM may also maintain tuning parameters for use in sending read data through the memory bus.

This iterative training using a host processor, and a Multi-Purpose Command (MPC) FIFO requires that the SDRAM system remain unavailable for mission mode operation while the training is being performed. Mission mode operation as used herein refers to a mode of performing the mission of the device, e.g., not startup, training calibration, maintenance, etc. The time and resources required to perform the iterative training reduce the system availability. Accordingly, such training is performed infrequently. However, with increasing memory speeds, training becomes more important to maintain write and read accuracy.

In examples herein, training may be performed at the PHY hardware and using a local Linear Feedback Shift Register (LFSR) or similar simple hardware mechanism. Using a local LFSR means that long burst training may be performed without relying on protocol base commands from a host processor. The training may be performed using only the hardware at each end of the memory bus. This allows the training to be performed much more quickly than with many software driven approaches. The training may be started by a suitable software command or interrupt. The training may be performed independently of the processing system when suitable conditions arise, such as a startup sequence, a wake from idle mode, or a pause in other processes. In examples herein the host and the memory each have a local LFSR. As a result, the training sequence is only sent in one direction greatly reducing the time required for training. The described training is faster, lower power, and does not consume host processor resources. It may be started at the host PHY independent of the host processor or upon command or interrupt from the host processor.

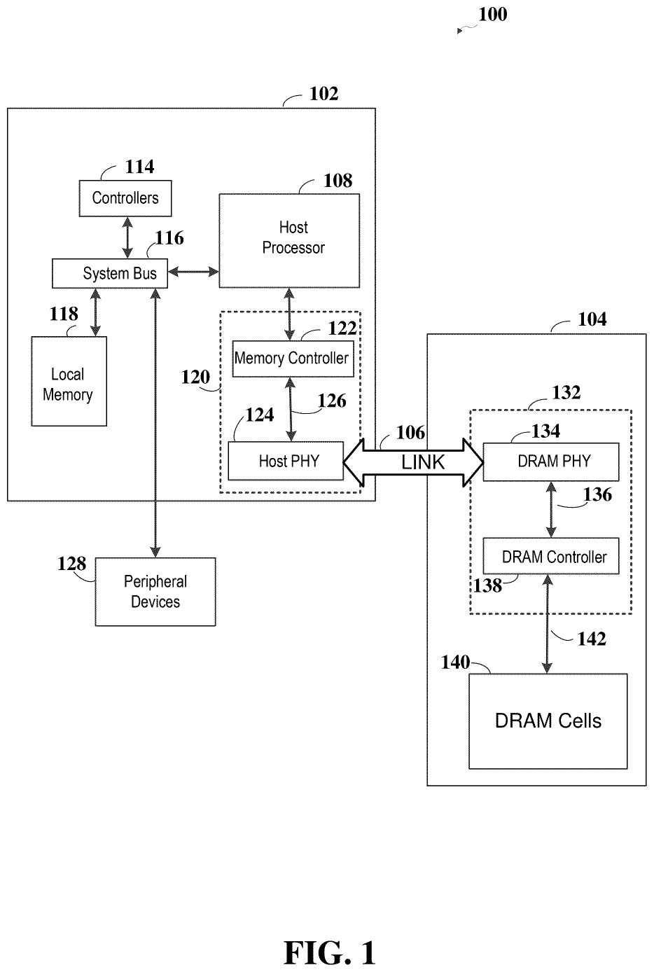

FIG. 1 is a block diagram of an apparatus with a host and a memory coupled through a memory bus. The apparatus 100 includes a host 102 as a first node of a memory bus or link 106 and a device, e.g., volatile memory or DRAM 104 as a second node of the link 106. The diagram shows only some features and components. A practical system may include many components including sensors, actuators, radios, data connections, and power supply and distribution components. The host 102 may be integrated on a first chip (e.g., system-on-chip or SoC), and the DRAM 104 may be integrated on a second chip. In another aspect, the host and/or device may be integrated in first and second packages, e.g., SiP, first and second system boards with multiple chips, or in other hardware or any combination.

In the example shown in FIG. 1, the host 102 and the DRAM 104 are coupled by a single link 106. There may be many more devices coupled though other links. The link 106 may be formed with wire leads, conductive traces, socket and plug, or cables. The link 106 carries mission-mode and training-mode traffic between the host 102 and the DRAM 104. The DRAM 104 may be, for example, a Low-Power DDR-SDRAM (LPDDR) operating in accordance with an LPDDR specification promulgated by JEDEC. The LPDDR specification may be, for example, LPDDR5, LPDDR6, or another specification. The host 102 may be implemented as a system-on-chip (SoC) that includes multiple processors and other devices, interconnected by data buses or other interconnections (not shown for purposes of clarity). In some examples, the link 106 may be a chip-to-chip or a die-to-die link between the host 102 and the DRAM 104, the host 102 and the DRAM 104 being on separate dies. In other examples, the link 106 may be an in-die link, the host 102 and the DRAM 104 being on the same die. In some examples, the link 106 may be through packages and circuit boards, the host 102 and the DRAM 104 being in separate chips or separate circuit boards.

The apparatus 100 may include, for example, one of: a computing system (e.g., server, datacenter, desktop computer), a mobile or portable computing device (e.g., laptop, cell phone, vehicle, etc.), an Internet of Things (IoT) device, a virtual reality (VR) system, an augmented reality (AR) system, etc. The host 102 may include at least one host processor 108. The host 102 may further include other controllers 114, such as, for example, a central processing unit (CPU), a digital signal processor (DSP), a graphics processing unit (GPU), a neural processing unit (NPU), etc., which may perform one or more mission-mode computing functions, such as data processing, data communication, graphic display, camera operation, AR or VR rendering, image processing, etc. The controllers 114 may be coupled to the host processor 108 through a system bus 116 coupled to both the controllers and the host processor. The host processor 108 may also be coupled to local cache or read-only memory (ROM) 118 through the system bus 116 and to a variety of different internal and external peripheral devices 128 through the system bus, e.g., user interface, mass memory, external sensors, actuators, radios, etc.

The host processor 108 is coupled to a memory interface 120. The memory interface includes a memory controller 122 coupled to the host processor and a host physical interface (PHY) 124 coupled to the memory controller 122 through a bus 126. The DRAM 104 may service write and read operations initiated by such other controllers 114 through the host processor 108 and read and write operations of the host processor 108. The host 102 may communicate data and commands with the DRAM 104 via the link 106, either directly under the control of a processor or indirectly by a processor via a memory controller 110 or other intermediary device.

The DRAM 104 includes a DRAM interface 132 that includes a DRAM PHY 134 coupled to the link 106 to receive write and read commands and to receive and transmit data. The DRAM PHY 134 is coupled through a data connector 136 to a DRAM controller 138. The DRAM controller 138 maintains memory maps and configuration and status registers and writes data to and reads data from DRAM cells 140 of the DRAM 104. The DRAM controller 138 may include data buffers, programming instructions and logic to control operations performed with the host 102 though the link. There may be multiple DRAMs 104 coupled to the host 102 through the same or additional links 106. The DRAM cells 140 may be on one or more dies and the dies may be the same or different dies from the DRAM interface 132.

The host processor 108 is coupled to the DRAM 104, e.g. DDR SDRAM, through the link 106, e.g., an LPDDR memory bus. For high-speed operation, the host processor 108 initiates a training operation using the hardware coupled to the link 106. In examples described herein, the training hardware is in the host PHY 124 and the DRAM PHY 134 of the apparatus 100, however, some components may be configured in other locations of the apparatus 100. The training approach described herein may also be adapted to another type of bus and another end component attached to the bus. To train write operations on the memory bus, the host PHY 124 sends a Pseudo-Random Binary Sequence (PRBS) through the link 106 to the DRAM 104 on the other end of the link. The DRAM 104 receives the PRBS at the DRAM PHY 134 and compares the sequence against the expected sequence. The DRAM PHY 134 then returns a score back to the host PHY 124. The score may be a pass/fail score, or it may be a value indicating a number of accurately received bits in the sequence.

The write or read or both training operations may be repeated multiple times with different tuning parameters to determine which parameters obtain a passing score or the highest score. The tuning parameters set the delay that is applied to the data in a write or read operation. A write data tuning parameters sets a delay to determine the phase of the write data relative to the write clock. A read data tuning parameter sets a delay to determine the phase of the read data relative to the read clock. Additional tuning parameters may also be calibrated during training including for data bus voltages. The tuning parameters with the best result are then used for later bus communications. The training operations are performed at low bus data rates to allow the PRBS to be successfully received before the tuning parameters are trained. After training, the tuning parameters are suitable for higher bus data rates.

The PRBS is randomized in order to overcome any systemic errors or biases in the memory bus. For example, the PRBS may be randomized to allow leading and trailing edges of data pulses to be detected with proper tuning parameters. In some examples, the sequence may be stored in local memory or generated independently on each side of the memory bus. A pseudo-random number generator may be used at the host PHY 124 and the DRAM PHY 134 to generate suitable matching sequences. This allows for a very long test sequence to be generated without consuming memory storage space. Any suitable pseudo-random number generator, such as a Linear Feedback Shift Register (LFSR) may be used. An LFSR allows for a predictable long sequence to be generated on both sides of the memory bus provided that both LFSR's start with the same seed value.

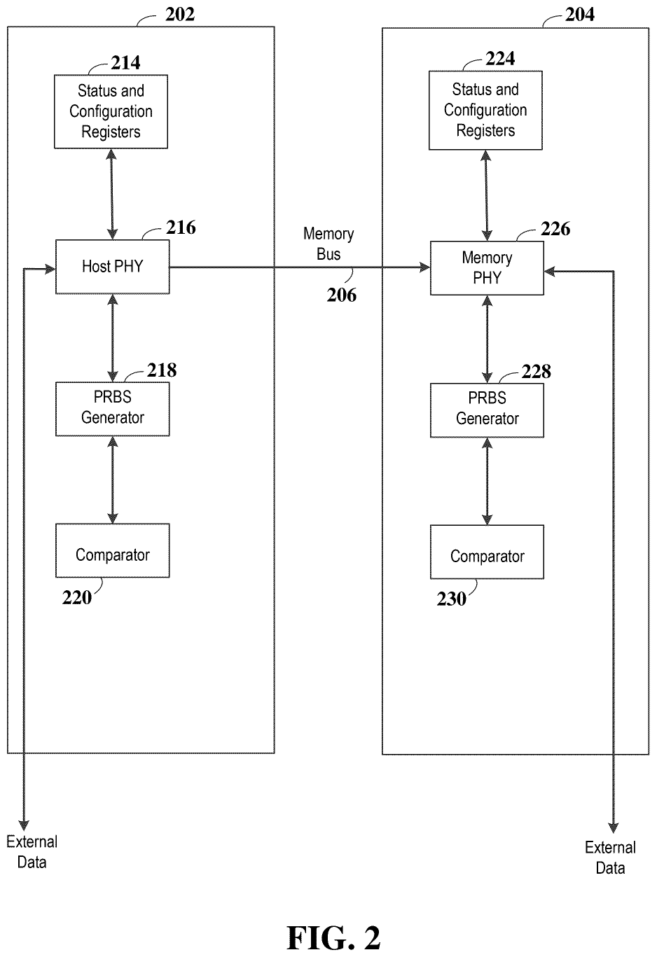

FIG. 2 is a simplified block diagram of interfaces of a memory bus for training the memory bus. A memory interface 202 on the host side has a host PHY 216 coupled to a memory bus 206. The host PHY 216 is coupled to external data of the host to send and receive data and commands that the host PHY 216 in turn sends and receives through the memory bus 206. The memory bus 206 is coupled to a memory PHY 226 of a DRAM interface 204 to receive write data from the host PHY 216 and to send read data to the host PHY 216. The memory PHY 226 is coupled to external data of the memory to store the write data and to provide the read data.

The host PHY 216 is coupled to a pseudo-random bit sequence (PRBS) generator that is configured to generate a PRBS at the host and to a comparator 220 to compare a PRBS received through the memory bus 206 to a local PRBS from the PRBS generator 218. The host PHY 216 is coupled to status and configuration registers 214 to store tuning parameters for the memory bus 206 and other parameters. The host PHY 216 sends the PRBS from the host PRBS generator 218 to a memory PHY 226 of a DRAM interface 204 through the memory bus 206 and receives a score from the memory PHY 226 based on comparing the PRBS to a PRBS of the memory.

The memory interface 202 may then adjust tuning parameters for the timing or voltage of the memory bus based on the score and store the tuning parameters in the status and configuration registers 214. The host PHY 216 uses these calibrated tuning parameters send data through the memory bus 206. The memory PHY 226 receives the PRBS from the host PHY 216 through the memory bus 206. The memory PRBS generator 228 generates a PRBS and the comparator 230 generates a score based on comparing the PRBS received from the host PHY 216 and the local PRBS. These results are sent to the host PHY 216 for use in adjusting the tuning parameters.

Similarly, the host PHY 216 may command the DRAM interface 204 to send a PRBS to the memory interface 202. The memory PHY 226 receives the command. The memory PRBS generator 228 generates a PRBS that is sent by the memory PHY 226 to the host PHY through the memory bus 206. The host PHY 216 receives the PRBS from the memory PHY 226 through the memory bus 206. The host PRBS generator 218 generates a PRBS and the comparator 220 generates a score based on comparing the PRBS received from the memory PHY 226 and the local PRBS from the local PRBS generator 218. These results are then used in adjusting the tuning parameters for read operations, e.g., read data delay and VREF. The tuning parameters are sent by the host PHY 216 to the memory PHY 226 and may be stored in status and configuration registers 224 of the DRAM interface 204. The memory PHY 226 may then send read data to the host PHY 216 in accordance with the tuning parameters stored in the status and configuration registers.

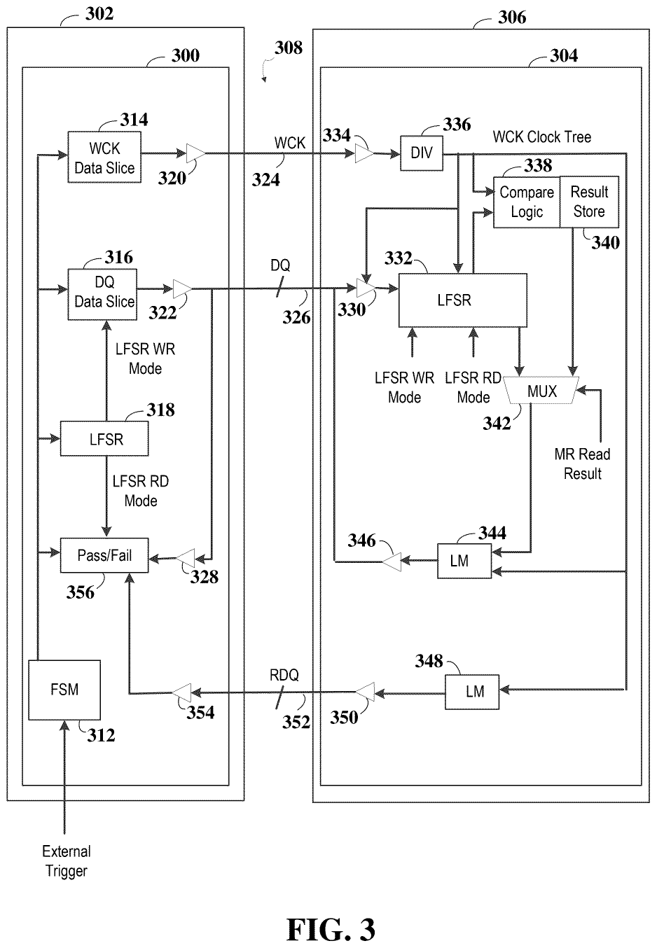

FIG. 3 is a block diagram of a host PHY 300 of a host 302 coupled to a DRAM PHY 304 of a DRAM 306 through a memory bus 308 configured for training. An external trigger is connected to a finite state machine (FSM) 312 or other controller that is configured to start a training process for the memory bus 308. The FSM 312 is coupled to a WCK clock slice 314 and a DQ data slice 316 for write operations. The FSM 312 is also coupled to a pseudo random number generator, e.g. a host LFSR 318 to initiate the generation of a training sequence. While an LFSR is shown any other suitable sequence generation or production component may be used instead. The training sequence is sent from the LFSR to the DQ data slice 316 through a line amplifier 322 coupled to a multiple line data bus (DQ) 326 to be written to the DRAM 306 under training conditions. The WCK clock slice 314 sends a clock signal through a line amplifier 320 on the clock line WCK 324. The timing of the WCK 324 and the DQ are varied relative to each other during the training to determine a suitable relative delay. In some aspects a training operation also sets an appropriate voltage for the DQ bus 326 by varying the voltage applied by the line amplifiers. The external trigger may be generated by the host 302, including a memory controller, a startup state machine, or any other suitable external component.

At the DRAM 306, the training sequence from the host LFSR 318 is received over the DQ 326 through a DQ line amplifier 330 at a DRAM pseudo-random number generator, e.g. a DRAM LFSR 332. The DRAM PHY 304 also receives the WCK 324 through a clock line amplifier 334. For training purposes, the clock line amplifier 334 is coupled to a clock divider 336 that sends the divided clock signal, based on the received WCK 324 to the DQ line amplifier 330. Accordingly, the data lines on the DQ 326 are received using the clock signal at WCK 324. The divided clock from the clock divider 336 is also received at the DRAM LFSR 332. The LFSR generates the same training sequence that was generated by the host LFSR 318. The received training sequence from the DQ 326 and the generated sequence from the DRAM LFSR 332 are provided to compare logic 338 that determines whether the two training sequences match. In some aspects a score is generated by comparisons for each relative clock delay setting. In some aspects a single pass/fail result is recorded. The compare logic 338 is coupled to a result store 340 that stores the result of each training sequence from the compare logic.

The results from the result store 340 are sent back to the host 302 through the host PHY 300. The number of bytes to read the results from the DRAM may be much less than the number of bytes in the training sequence. This data reduction allows for faster training operations. The results are provided to a latch multiplexer 342 that is coupled to a latch multiplexer 342 to serialize the results and send the results through a line amplifier 346 to the DQ 326 back to the host. The results are received at the host PHY 300 at a DQ line amplifier 328 that is coupled to a pass/fail module 356 to record the pass/fail or other type of result. In another aspect, the DRAM writes the results to configuration and status registers of the PHY. The result store 340 may serve, at least in part as such configuration and status registers. The memory controller of the host PHY may use a Mode Register Read (MRR), to read the results stored in the result store 340. The results data may be used to perform adjustments within the host PHY or provided to an external processor to interpret the results and provide the adjustments in response to the training.

As shown the FSM 312 is coupled to the host LFSR 318 to cause the host LFSR 318 to generate a training sequence and to the DQ data slice 316 to cause the DQ data slice to send the training sequence to the DRAM 306. The training sequence may be sent as any write data is sent through the bus 308. At the DRAM 306, the DRAM LFSR 332 also receives an LFSR RD Mode signal. The LFSR RD Mode signal may be received as a command from the host PHY 300 to trigger the read mode at the DRAM LFSR 332. Similarly, the latch multiplexer 342 also receives an MR read result signal to cause the multiplexer to select the result store 340 input to provide to the latch multiplexer 342. These signals in the DRAM PHY may be generated, for example by the memory controller of the DRAM 306 in response to commands received from the host 302 through the bus 308. The DRAM PHY 304 may include a corresponding state machine to drive the training operation.

To test the bus 308 in the opposite direction corresponding to read operations from the DRAM 306 to the host 302, the DRAM LFSR 332 receives an LFSR WR Mode signal to cause the LFSR to transition to a write mode. The DRAM LFSR 332 generates a training sequence to send to the host PHY 300 in the manner of responding to a read command over the bus 308. The latch multiplexer 342 also receives an inverse MR Read Result signal to connect the training sequence to the latch multiplexer 342. From the latch multiplexer 342, the training sequence from the DRAM LFSR 332 is sent through the line amplifier 346 across the data bus (DQ) 326. The received training sequence is then routed through a receive line amplifier 328 of the host PHY 300 for a comparison test at a pass/fail module 356. The pass/fail module 356 is coupled to the host LFSR 318 to compare the sequence from the host LFSR 318 to the sequence from the DRAM LFSR 332 that was received through the DQ 326. The results of the comparison at the pass/fail module 356 are used to perform adjustments within the host PHY or provided to an external processor to interpret the results and provide the adjustments in response to the training.

The clock signal for the read operation during training is based on the WCK 324 from the host. The clock divider 336 is coupled to a WCK clock tree that sends the clock received on the WCK 324 throughout the DRAM PHY 304. In addition to providing the clock to the compare logic 338, the clock is provided to the latch module 344 to time read data to the DQ 326. In addition, the clock is provided to a second latch module 348 that sends the clock through a line amplifier 350 to a read clock line (RDQ) 352 of the bus 308. The RDQ 352 is coupled through an RDQ line amplifier 354 of the host PHY 300 to the pass/fail module 356. The RDQ 352 represents the read clock that would be sent in a normal read operation from the DRAM 306 to the host 302. As the clock sent through WCK 324 is adjusted at the host during read operations the clock over the RDQ 352 is adjusted with it. By modifying the relative delay of the RDQ 352 and the DQ 326 for read operations, the bus is trained.

The block diagram of FIG. 3 illustrates only some of the components of a host PHY 300 and a DRAM PHY 304 that are involved for training. Additional connections may be used to provide write data to the host PHY and to send read data from the host PHY to the host 302. There may be various clock sources and distributors, data buffers, memory maps and other components. Memory controllers may be used to send and receive commands and to control the illustrated components to perform the described training. In addition, the same training process may be used with constant clock timing and variations in the voltage applied to the bus. A preferred bus voltage may be determined by modifying the voltage between writing and reading training sequence. The host 302 and DRAM 306 contain many other components not shown.

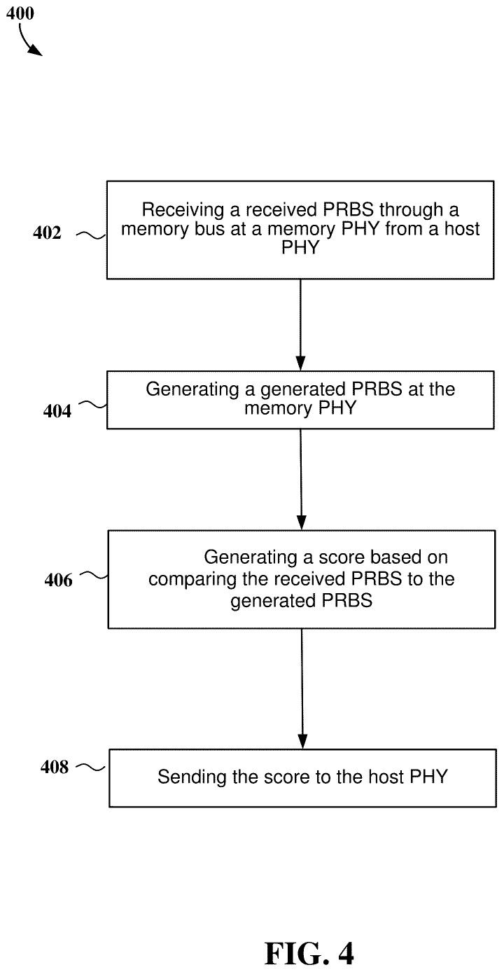

FIG. 4 is a process flow diagram of an example training mode operation at a memory PHY, e.g., a DRAM PHY. At 402, receiving a received Pseudo-Random Binary Sequence (PRBS) through a memory bus at a memory physical interface (PHY) from a host PHY is performed. The memory bus may have data lines and a write clock and the PRBS may be received through data lines of the memory bus with a write clock. The PRBS may be received in accordance with a set of tuning parameters. A write training mode may be enabled in some examples by an MRW command from the host PHY.

At 404, a generated PRBS is generated at the memory PHY. The PRBS may be generated by an LSFR. In some aspects, the memory PHY is configured to receive an initial seed for the LSFR from the host PHY through the memory bus before generating a PRBS. Additional parameters may also be received from the host PHY for the memory PHY to use to configure the LSFR, e.g., length, taps, etc. At 406, a score is generated based on comparing the received PRBS and the generated PRBS. In aspects, the score is a pass/fail score and may be associated with the tuning parameters in accordance with which a particular PRBS is sent.

At 408, sending the score to the host PHY through the memory bus is performed. In aspects, an MRR command is received from the host PHY through the memory bus to read out a result store in which the scores are saved and to send the score or scores to the host PHY through the memory bus.

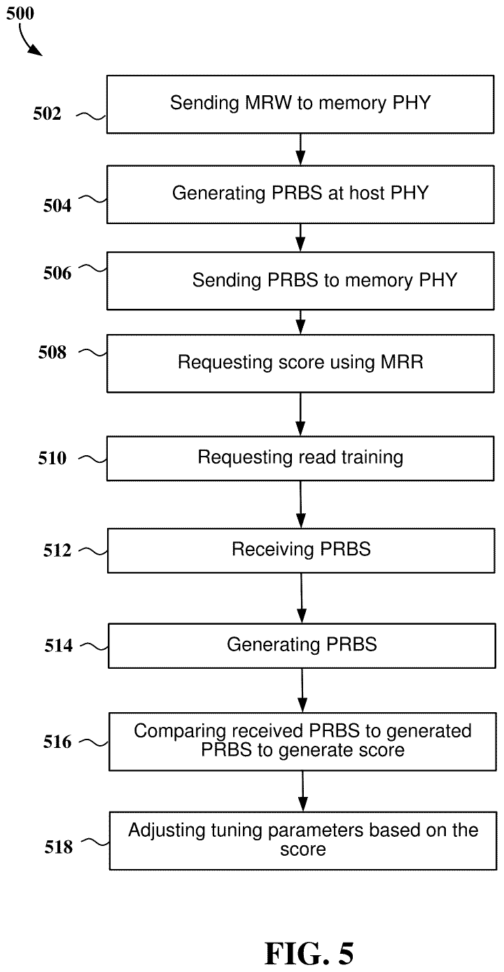

FIG. 5 is a process flow diagram of an example training mode operation at a host PHY. At 502 a memory refresh write (MRW) command is sent from the host to a memory PHY, e.g., a DRAM PHY as described above. At 504 a PRBS is generated at the host PHY. AT 506 the PRBS is sent in accordance with a selected set of tuning parameters from the host PHY to the memory PHY through the memory bus. The memory then compares the received PRBS to its own local PRBS and generates a score based on the comparison. At 508, the host requests the score using a memory refresh read (MRR) command. The score may be used by the host to adjust or select the tuning parameters. These tuning parameters are stored locally at the memory interface of the host e.g. in configuration registers, for use in sending write data from the host to the memory over the memory bus. The tuning parameters may include a relative delay of the write data with respect to the write clock and a voltage of the write data, among other parameters. The host may send multiple PRBS in accordance with different tuning parameters before requesting any scores. The PRBS is sent in accordance with tuning parameters in that the phase of the data and the clock lines or the voltage on these lines is determined by the selected tuning parameters.

For training the read operations through the memory bus at 510 the host PHY request read training. The memory then generates a PRBS and sends the PRBS in accordance with selected tuning parameters from the memory PHY to the host PHY through the memory bus. At 512, the host receives the PRBS. At 514, the host generates a local PRBS. AT 516, the PRBS compares the PRBS received from the memory PHY through the bus to the PRBS generated locally and generates a score. Again, if the PRBS from the memory PHY is received accurately, then these two should match. The closer the match, the better the selected tuning parameters. At 518, the tuning parameters for read operations are adjusted or selected based on the score. These tuning parameters may be sent from the host to the memory and stored locally at the memory interface of the memory, e.g., in configuration registers, for use in sending read data from the memory to the host over the memory bus. The tuning parameters may include a relative delay of the read data with respect to the read clock and a voltage of the read data, among other parameters.

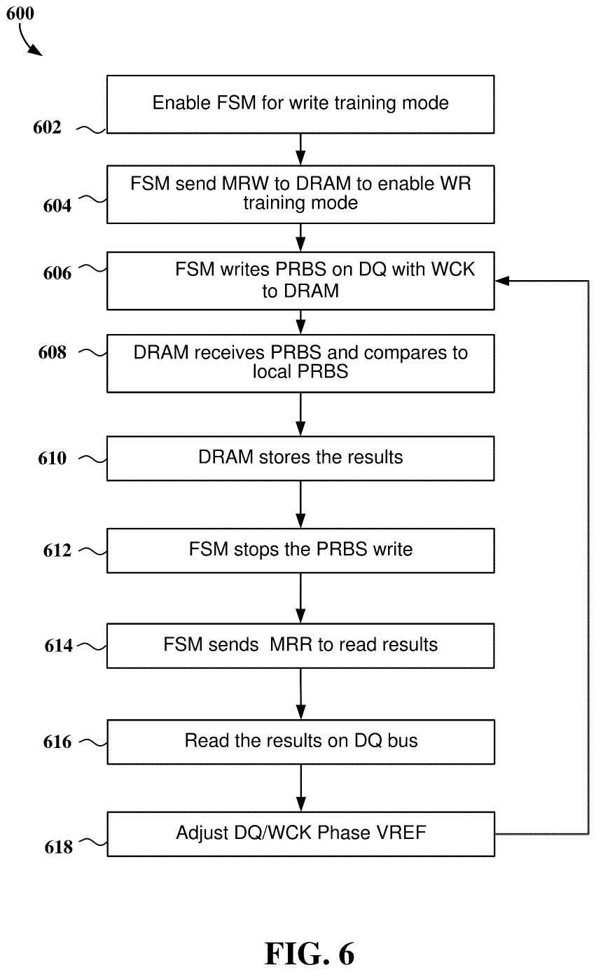

FIG. 6 is a process flow diagram of an example write training mode operation. After a command is received from external host components or generated at the host PHY then at 602, an FSM or other controller is enabled to drive the write training mode. At 604 the host FSM sends a Memory Refresh Write (MRW) command to the DRAM to enable the write training mode at the DRAM. MRW command is defined for DDR6 and other memory bus standards and is used to calibrate the memory bus and connected components for high-speed write operations. For other memory bus configurations, another command may be used. At 604, the FSM starts the LFSR or other PRBS generator or source. The LFSR sends the PRBS pattern and WCK to the DRAM PHY. For these operations, the DQ and WCK phase are set to an initial value or to the current value. The reference voltage (VREF) of the memory bus is also set to an initial or current value. For an LFSR, the host LFSR and the DRAM LFSR must be initialized to the same configuration and same starting value, e.g., initial seed. This will maintain the same PRBS being generated by the host LFSR and the DRAM LFSR.

At 606, the LFSR sequence is sent to the DRAM, by writing the PRBS on the DQ with the WCK to the DRAM. In some aspects the PRBS is a long DQ burst with a 1K, 2K, or 4K pattern. At 608 the DRAM starts its LFSR or other PRBS. It receives the write sequence from the host PHY, e.g. on the first rising edge of the WCK, and compares the received PRBS to the locally generated PRBS. At 610 the DRAM stores the result of the comparison. This may a simple pass/fail, a sequence of pass/fails for bytes or blocks of the PRBS or another measure. At 612 the FSM at the host stops sending the PRBS and the WCK to the DRAM.

At 614 the FSM send a memory refresh read (MRR) command to the DRAM to read out the stored results that were determined by the comparison at the DRAM. At 616, the results are sent to the host PHY, e.g. asynchronously on the DQ bus. At 618, the tuning parameters are adjusted for the next sequence of the training operation. As an example, the host may adjust the DQ/WCK phase or adjust the VREF. The process may repeat by returning to operation 606 with different parameters to try a new write operation. The final tuning parameters, among others, from the repetitions of this process may be stored at the host to send write data in accordance with the tuning parameters.

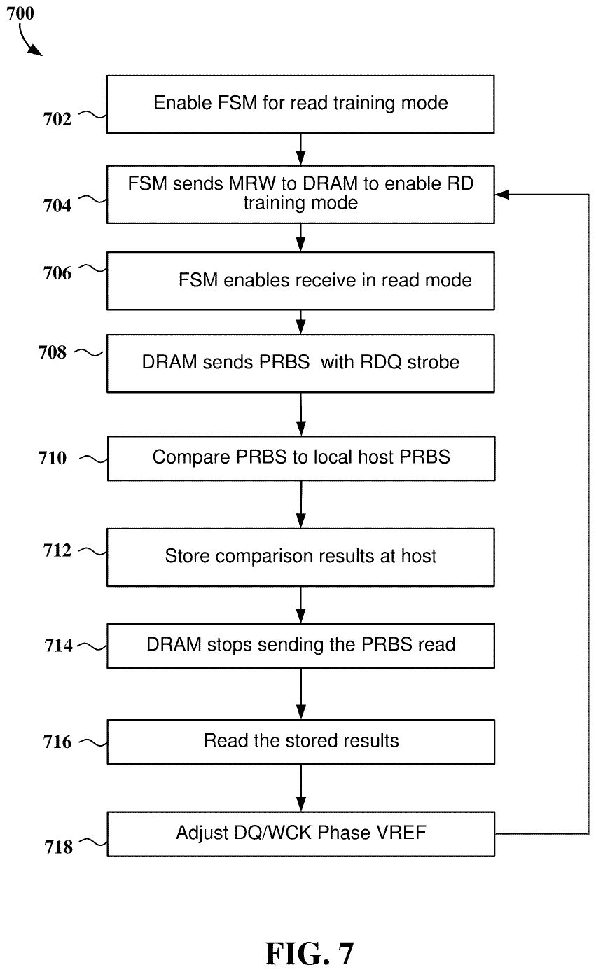

FIG. 7 is a process flow diagram of an example read training mode operation. After a command is received from external host components or generated at the host PHY then at 702, an FSM or other controller is enabled to drive the read training mode. At 704 the host FSM sends a MRW command or similar command to the DRAM to enable the read training mode at the DRAM. At 704, the FSM starts the LFSR or other PRBS generator or source. The LFSR sends the PRBS pattern and WCK to the DRAM PHY. For these operations, the DQ and RDQ phase are set to an initial value or to the current value. The reference voltage (VREF) of the memory bus is also set to an initial or current value. For an LFSR, the host LFSR and the DRAM LFSR must be initialized to the same configuration and same starting value, e.g., initial seed. This will maintain the same PRBS being generated by the host LFSR and the DRAM LFSR.

At 706, the FSM at the host enables receive operations in a read mode at the host PHY. At 708, the DRAM starts its LFSR or other PRBS source and starts sending the PRBS on the DQ with the RDQ strobe to the host as read data. In some aspects the PRBS is a long DQ burst with a 1K, 2K, or 7K pattern. At 708 the DRAM starts its LFSR or other PRBS. At 710, the host receives the read sequence from the DRAM PHY, e.g. on the first rising edge of the RDQ, and compares the received PRBS to the locally generated PRBS. At 712 the host stores the result of the comparison. This may a simple pass/fail, a sequence of pass/fails for bytes or blocks of the PRBS or another measure. At 714 the DRAM stops sending the PRBS and the RDQ to the host. In some aspects, this occurs as the PRBS has a fixed length and the entire length has been transmitted.

At 716 the FSM or other controller reads the locally stored results that were determined by the comparison at the host. At 718, the results are used to adjust the tuning parameters for the next sequence of the training operation. As an example, the host may adjust the DQ/WCK phase or adjust the VREF. The process may repeat by returning to operation 704 with different parameters to try a new read operation. The final calibrated tuning parameters, among others, from the repetitions of this process may be stored at the memory to send read data in accordance with the tuning parameters.

By using a matching PRBS in both the host PHY and the DRAM PHY, the comparisons may be made locally without engaging higher layers. By using a FSM at the host PHY, the training operation may be managed within the host PHY without engaging higher layers. This allows for a faster training operation without consuming higher layer resources. The following provides an overview of examples of the present disclosure.

Example 1: A memory comprising: a memory physical interface (PHY) of a memory coupled to a memory bus and configured to receive a received Pseudo-Random Binary Sequence (PRBS) through the memory bus from a host PHY; a PRBS generator configured to generate a generated PRBS; and compare logic configured to generate a score based on comparing the received PRBS and the generated PRBS, the memory PHY further configured to send the score to the host PHY.

Example 2: The memory of example 1, wherein memory bus comprises data lines and a write clock line and wherein the memory PHY is configured to receive the PRBS through the data lines of the memory bus based on a timing of the write clock,

Example 3: The memory of example 1 or 2, further comprising a Linear Feedback Shift Register (LFSR) configured to generate the generated PRBS.

Example 4: The memory of example 3, wherein the memory PHY is further configured to receive an initial seed for the LFSR from the host PHY through the memory bus before the generating the generated PRBS.

Example 5: The memory of any one or more of the above examples, wherein the compare logic is configured to generate a pass/fail score.

Example 6: The memory of any one or more of the above examples, further comprising a result store, wherein the memory PHY is configured to receive a memory refresh read (MRR) command from the host PHY through the memory bus and to read out the score from the result store and send the score through the memory bus in response to the MRR.

Example 7: A method comprising: receiving a received Pseudo-Random Binary Sequence (PRBS) through a memory bus at a memory physical interface (PHY) from a host PHY; generating a generated PRBS at the memory PHY; generating a score based on comparing the received PRBS and the generated PRBS; and sending the score to the host PHY through the memory bus.

Example 8: The method of example 7, wherein the receiving a received PRBS comprises receiving the PRBS through data lines of the memory bus with a write clock.

Example 9: The method of example 7 or 8, further comprising receiving a Memory Refresh Write (MRW) command from the host PHY to enable a write training mode at the memory PHY before the receiving the received PRBS.

Example 10: The method of any one or more of examples 7-9, wherein the generating the generated PRBS comprises generating the PRBS using a Linear Feedback Shift Register (LFSR).

Example 11: The method of example 10, further comprising receiving an initial seed for the LFSR from the host PHY before the generating the generated PRBS.

Example 12: The method of example 10, or 11, further comprising receiving an LFSR parameter from the host PHY before the generating the generated PRBS.

Example 13: The method of any one or more of examples 7-12, wherein the generating the score comprises generating a pass/fail score.

Example 14: The method of any one or more of examples 7-13, wherein the sending the score comprises receiving a memory refresh read (MRR) command from the host PHY to read out the score and sending the score through the memory bus in response to the MRR command.

Example 15: The method of example 14, further comprising: storing the score in a result store; and sending the score from the result store.

Example 16: The method of example 15, wherein the result store comprises configuration and status registers of the memory.

Example 17: The method of any one or more of examples 7-16, further comprising: receiving a read training command from the host PHY through the memory bus; generating a generated read PRBS at the memory PHY; and sending the generated read PRBS to the host PHY with a read clock strobe through the memory bus.

Example 18: A memory apparatus comprising: means for receiving a received Pseudo-Random Binary Sequence (PRBS) through a memory bus at a memory physical interface (PHY) from a host PHY; means for generating a generated PRBS at the memory PHY; means for generating a score based on comparing the received PRBS and the generated PRBS; and means for sending the score to the host PHY through the memory bus.

Example 19: The memory apparatus of example 18, further comprising means for storing the score, wherein the means for sending the score to the host PHY comprises means for receiving a memory refresh read command from the host PHY, reading the score from the means for storing and for sending the score in response to the MRR command.

Example 20: The memory apparatus of example 18 or 19, further comprising means for generating a second generated PRBS at the memory PHY; and means for sending the second generated PRBS in response to a read training command from the host PHY.

Example 21: A memory interface comprising: a PRBS generator configured to generate a PRBS; a host PHY coupled to a memory bus and configured to send the PRBS to a memory through the memory bus and configured to receive a score from the memory based on comparing the PRBS to a PRBS of the memory; and a memory controller to adjust tuning parameters based on the score.

Example 22: The memory interface of example 21, wherein the memory controller is further configured to send an MRW command to the memory to enable a write training mode at the memory before the sending the PRBS.

Example 23: The memory interface of example 21 or 22, wherein the memory controller is configured to send an initial seed for an LFSR of the memory before the sending the PRBS.

Example 24: The memory interface of any one or more of examples 21-23, wherein the memory controller is configured to send a MRR command to the memory to command the memory to read the score.

Example 25: The memory interface of any one or more of examples 21-24, wherein the memory controller is configured to send a read training command to the memory, wherein the PRBS generator is configured to generate a read PRBS, wherein the host PHY is configured to receive a memory PRBS through the memory bus, and wherein the memory controller is configured to adjust the tuning parameters in response to a comparison of the read PRBS and the memory PRBS.

Example 26: A method comprising: generating a PRBS; sending the generated PRBS to a memory with tuning parameters through a memory bus; receiving a score from the memory based on comparing the PRBS to a PRBS of the memory; and adjusting the tuning parameters based on the score.

The foregoing description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein and are to be accorded the full scope consistent with the language of the claims, wherein reference to an element in the singular is not intended to mean “one and only one” unless specifically so stated, but rather “one or more.” The word “exemplary” is used herein to mean “serving as an example, instance, or illustration.” Any aspect described herein as “exemplary” is not necessarily to be construed as preferred or advantageous over other aspects.

As used herein, the term “coupled to” in the various tenses of the verb “couple” may mean that element A is directly connected to element B or that other elements may be connected between elements A and B (i.e., that element A is indirectly connected with element B), to operate certain intended functions. In the case of electrical components, the term “coupled to” may also be used herein to mean that a wire, trace, or other electrically conductive material is used to electrically connect elements A and B (and any components electrically connected therebetween). In some examples, the term “coupled to” may mean a transfer of electrical energy between elements A and B, to operate certain intended functions. In some examples, the term “electrically connected” may mean having an electric current or configurable to having an electric current flowing between the elements A and B. For example, the elements A and B may be connected via resistors, transistors, or an inductor, in addition to a wire, trace, or other electrically conductive material and components. Furthermore, for radio frequency functions, the elements A and B may be “electrically connected” via a capacitor.

The terms “first,” “second,” “third,” etc. may be employed for ease of reference and may not carry substantive meanings. Likewise, names for components/modules may be adopted for ease of reference and might not limit the components/modules. Modules and components presented in the disclosure may be implemented in hardware, software, or a combination of hardware and software. The terms “software” and “firmware” are used synonymously in this disclosure. The terms “bus system,” “interconnect,” “interconnect fabric,” “link,” etc., may provide that elements coupled to such a structure may exchange information therebetween, directly or indirectly. In such fashion, the “bus system” or related structure may encompass multiple physical connections as well as intervening stages such as buffers, latches, registers, etc.

Unless specifically stated otherwise, the term “some” refers to one or more. Combinations such as “at least one of A, B, or C,” “one or more of A, B, or C,” “at least one of A, B, and C,” “one or more of A, B, and C,” and “A, B, C, or any combination thereof” include any combination of A, B, and/or C, and may include multiples of A, multiples of B, or multiples of C. Specifically, combinations such as “at least one of A, B, or C,” “one or more of A, B, or C,” “at least one of A, B, and C,” “one or more of A, B, and C,” and “A, B, C, or any combination thereof” may be A only, B only, C only, A and B, A and C, B and C, or and B and C, where any such combinations may contain one or more member or members of A, B, or C.

All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. The words “module,” “mechanism,” “element,” “device,” and the like may not be a substitute for the word “means.” As such, no claim element is to be construed as a means plus function unless the element is expressly recited using the phrase “means for.”.

What is claimed is:

1. A memory comprising:
a memory physical interface (PHY) of a memory coupled to a memory bus and configured to receive a received Pseudo-Random Binary Sequence (PRBS) through the memory bus from a host PHY;
a PRBS generator configured to generate a generated PRBS; and
compare logic configured to generate a score based on comparing the received PRBS to the generated PRBS,
the memory PHY further configured to send the score to the host PHY.

2. The memory of claim 1, wherein the memory bus comprises data lines and a write clock line and wherein the memory PHY is configured to receive the PRBS through the data lines of the memory bus based on a timing of the write clock.

3. The memory of claim 1, further comprising a Linear Feedback Shift Register (LFSR) configured to generate the generated PRBS.

4. The memory of claim 3, wherein the memory PHY is further configured to receive an initial seed for the LFSR from the host PHY through the memory bus before the generating the generated PRBS.

5. The memory of claim 1, wherein the compare logic is configured to generate a pass/fail score.

6. The memory of claim 1, further comprising a result store, wherein the memory PHY is configured to receive a memory refresh read (MRR) command from the host PHY through the memory bus and to read out the score from the result store and send the score through the memory bus in response to the MRR.

7. A method comprising:
receiving a received Pseudo-Random Binary Sequence (PRBS) through a memory bus at a memory physical interface (PHY) from a host PHY;
generating a generated PRBS at the memory PHY;
comparing the received PRBS to the generated PRBS;
generating a score based on comparing the received PRBS and the generated PRBS; and
sending the score to the host PHY through the memory bus.

8. The method of claim 7, wherein the receiving a received PRBS comprises receiving the PRBS through data lines of the memory bus with a write clock.

9. The method of claim 7, further comprising receiving a Memory Refresh Write (MRW) command from the host PHY to enable a write training mode at the memory PHY before the receiving the received PRBS.

10. The method of claim 7, wherein the generating the generated PRBS comprises generating the PRBS using a Linear Feedback Shift Register (LFSR).

11. The method of claim 10, further comprising receiving an initial seed for the LFSR from the host PHY before the generating the generated PRBS.

12. The method of claim 10, further comprising receiving an LFSR parameter from the host PHY before the generating the generated PRBS.

13. The method of claim 7, wherein the generating the score comprises generating a pass/fail score.

14. The method of claim 7, wherein the sending the score comprises receiving a memory refresh read (MRR) command from the host PHY to read out the score and sending the score through the memory bus in response to the MRR command.

15. The method of claim 14, further comprising:
storing the score in a result store; and
sending the score from the result store.

16. The method of claim 15, wherein the result store comprises configuration and status registers of the memory.

17. The method of claim 7, further comprising:
receiving a read training command from the host PHY through the memory bus;
generating a generated read PRBS at the memory PHY; and
sending the generated read PRBS to the host PHY with a read clock strobe through the memory bus.

18. A memory apparatus comprising:
means for receiving a received Pseudo-Random Binary Sequence (PRBS) through a memory bus at a memory physical interface (PHY) from a host PHY;
means for generating a generated PRBS at the memory PHY;
means for generating a score based on comparing the received PRBS to the generated PRBS; and
means for sending the score to the host PHY through the memory bus.

19. The memory apparatus of claim 18, further comprising
means for storing the score,
wherein the means for sending the score to the host PHY comprises means for receiving a memory refresh read command from the host PHY, reading the score from the means for storing and for sending the score in response to the MRR command.

20. The memory apparatus of claim 18, further comprising
means for generating a second generated PRBS at the memory PHY; and
means for sending the second generated PRBS in response to a read training command from the host PHY.
